(19) United States
(12) Patent Application Publication
(10) Pub. No.: US 2012/0236894 A1
(43) Pub. Date: Sep. 20, 2012

(54) WAVELENGTH CONVERSION DEVICE, SOLID-STATE LASER APPARATUS, AND LASER SYSTEM

(75) Inventors: Takashi ONOSE, Oyama-shi (JP); Hakaru MIZOGUCHI, Oyama-shi (JP); Osamu WAKABAYASHI, Hiratsuka-shi (JP)

(73) Assignee: GIGAPHOTON INC., Oyama-shi (JP)

(21) Appl. No.: 13/367,099

(22) Filed: Feb. 6, 2012

Related U.S. Application Data
(60) Provisional application No. 61/442,486, filed on Feb. 14, 2011.

(30) Foreign Application Priority Data
Jun. 20, 2011 (JP) 2011136787

(51) Int. Cl. H01S 5/50; G02F 1/355

(52) U.S. Cl. 372/50.22; 359/326

(57) ABSTRACT

A wavelength conversion device in this disclosure may include: a nonlinear crystal including a first surface; a first film to be joined to the first surface and including at least one layer; and a first prism to be joined to the first film.

### CROSS-REFERENCE TO RELATED APPLICATIONS

The present application claims the benefit of U.S. Provisional Patent Application Ser. No. 61/442,486 filed Feb. 14, 2011, and Japanese Patent Application No. 2011-136787 filed Jun. 20, 2011.

### BACKGROUND

1. Technical Field

This disclosure relates to a wavelength conversion device, a solid-state laser apparatus, and a laser system.

2. Related Art

Typical excimer lasers as ultraviolet light sources for use in semiconductor lithography are KrF excimer lasers whose output wavelength is about 248 nm and ArF excimer lasers whose output wavelength is about 193 nm.

Most of the ArF excimer lasers are marketed as two-stage laser systems including an oscillator stage laser and an amplifier stage. Major components common to both the oscillator stage laser and the amplifier stage in two-stage ArF excimer laser systems include the following. The oscillator stage laser includes a first chamber, and the amplifier stage includes a second chamber. The first and second chambers contain laser gas (mixture gas of F₂, Ar, Ne, and Xe) sealed therein. The oscillator stage laser and the amplifier stage are provided with a high-voltage pulse power supply for supplying electric energy for exciting the laser gas. The oscillator stage laser and the amplifier stage may have separate high-voltage pulse power supplies or share a common high-voltage pulse power supply. Inside the first chamber, first discharge electrodes including a first anode and a first cathode that are connected to the high-voltage pulse power supply are provided. In a similar manner, second discharge electrodes including a second anode and a second cathode that are connected to the high-voltage pulse power supply are provided inside the second chamber.

The features specific to the oscillator stage laser include, for example, a line narrowing module. The line narrowing module typically includes one grating and at least one prism beam expander. A semitransparent mirror and the grating jointly constitute an optical resonator. The first chamber of the oscillator stage laser is arranged between the semitransparent mirror and the grating.

When an electric discharge occurs between the first anode and the first cathode of the first discharge electrodes, the laser gas is excited, emitting light upon releasing the excitation energy. The light is then subjected to wavelength selection by the line narrowing module and the resulting light is output as laser light from the oscillator stage laser.

A two-stage laser system whose amplifier stage is a laser including an oscillator is called a master oscillator/power oscillator (MOPO), while a two-stage laser system whose amplifier stage is not a laser (i.e., not provided with an oscillator) is called a master oscillator/power amplifier (MOPA). When laser light from the oscillator stage laser is present in the second chamber of the amplifier stage, control is performed so that an electric discharge occurs between the second anode and the second cathode of the second discharge electrodes. As a result, the laser gas in the second chamber is excited, the laser light is amplified, and the resulting light is output from the amplifier stage.

### SUMMARY

A wavelength conversion device according to one aspect of this disclosure may include: a nonlinear crystal including a first surface; a first film to be joined to the first surface and including at least one layer; and a first prism to be joined to the first film.

A solid-state laser apparatus according to another aspect of this disclosure may include: a laser configured to output laser light; an amplifier configured to amplify the laser light; and the above wavelength conversion device configured to convert a wavelength of the laser light after being amplified.

A laser system according to yet another aspect of this disclosure may include: the above solid-state laser apparatus; and an amplifying apparatus configured to amplify the laser light from the solid-state laser apparatus.

### BRIEF DESCRIPTION OF DRAWINGS

Some embodiments of this disclosure will be described below with reference to the accompanying drawings.

FIG. 1A is a schematic view illustrating an example of a solid-state laser apparatus including a wavelength conversion device and a two-stage laser apparatus including the solid-state laser apparatus in a first embodiment of this disclosure.

FIG. 1B is a schematic view illustrating an example of an amplifying apparatus in FIG. 1A.

FIG. 2 is a schematic view illustrating a wavelength conversion element in a second embodiment of this disclosure.

FIG. 3 is a schematic view illustrating a wavelength conversion element in a third embodiment of this disclosure.

FIG. 4 is a schematic view illustrating a wavelength conversion element in a fourth embodiment of this disclosure.

FIG. 5 is a schematic view illustrating a wavelength conversion element in a fifth embodiment of this disclosure.

FIG. 6 is a schematic view illustrating a wavelength conversion element in a sixth embodiment of this disclosure.

FIG. 7 is a schematic view illustrating a wavelength conversion element in a seventh embodiment of this disclosure.

### DESCRIPTION OF PREFERRED EMBODIMENTS

Selected embodiments of this disclosure will be described in detail with reference to the accompanying drawings. The embodiments described below are for illustrative purposes only, and are in no way intended to unduly limit what is described in this disclosure. In addition, not all the configurations or operations described in these embodiments are indispensable to put this disclosure into practice. It should be noted that the same reference numerals refer to the same components and duplicate description thereof is omitted. The description will be given in the order below.

### TABLE OF CONTENTS

### 1. Overview

### 2. Definition of Terms

### 3. Laser System Including Solid-State Laser Apparatus Having Wavelength Conversion Device and ArF Amplifier: First Embodiment

3.1 Configuration

3.2 Operations

4. Wavelength Conversion Device Including Two Prisms Brought into Optical Contact with Nonlinear Optical Crystal: Second Embodiment

4.1 Configuration

4.2 Operations

4.3 Effect(s)

5. Wavelength Conversion Device Including Oxide Film Coated Prism Brought into Optical Contact with Nonlinear Optical Crystal: Third Embodiment

5.1 Configuration

5.2 Effect(s)

6. Wavelength Conversion Device Including Prism Brought into Optical Contact with Oxide or Fluoride Film Coated Nonlinear Optical Crystal: Fourth Embodiment

6.1 Configuration

6.2 Effect(s)

7. Wavelength Conversion Device Including Prism Film Brought into Optical Contact with Nonlinear Optical Crystal Film: Fifth Embodiment

7.1 Configuration

7.2 Effect(s)

8. Wavelength Conversion Device Including Prism Brought into Optical Contact with Nonlinear Optical Crystal Having Buffer Layers and Films Thereon: Sixth Embodiment

8.1 Configuration

8.2 Effect(s)

9. Wavelength Conversion Device Including One Prism Brought into Optical Contact with Film Coated Nonlinear Optical Crystal: Seventh Embodiment

9.1 Configuration

9.2 Operations

9.3 Effect(s)

### 1. OVERVIEW

In the embodiments described below, a surface of a nonlinear optical crystal may be coated with a film. This film may be brought into optical contact with a surface of a prism.

### 2. DEFINITION OF TERMS

A KBBF crystal is a nonlinear optical crystal represented by the chemical formula: KBe₂BO₃F₂. Burst oscillation means generating pulsed laser light at a predetermined repetition rate for a certain period. An optical path means a path through which laser light propagates. Optical contact means a method for closely joining surfaces having a surface accuracy (or a surface roughness) at or above a certain level. The level of the surface accuracy or the surface roughness required for each surface to be joined varies depending on its material. For some materials, after the surfaces are joined, they may be heated to facilitate molecular motion at the boundary and increase joining strength.

### 3. LASER SYSTEM INCLUDING SOLID-STATE LASER APPARATUS HAVING WAVELENGTH CONVERSION DEVICE AND ArF AMPLIFIER

### First Embodiment

### 3.1 Configuration

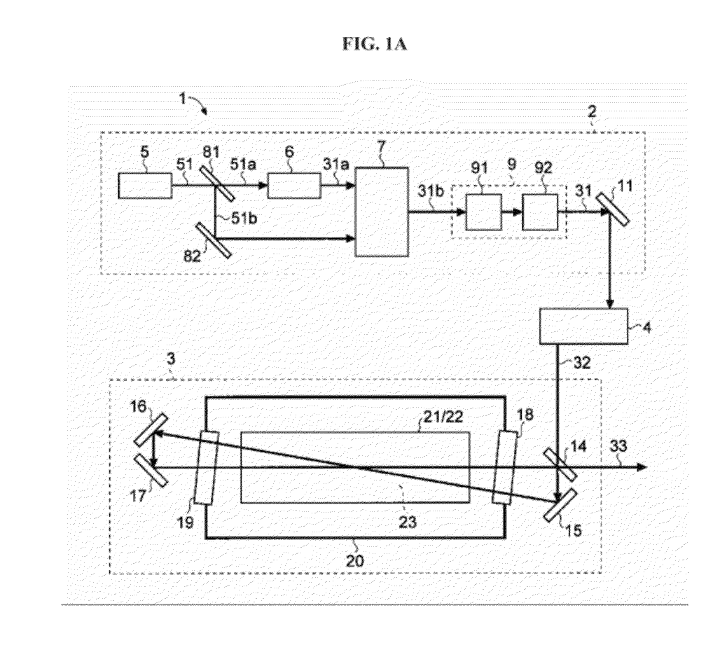

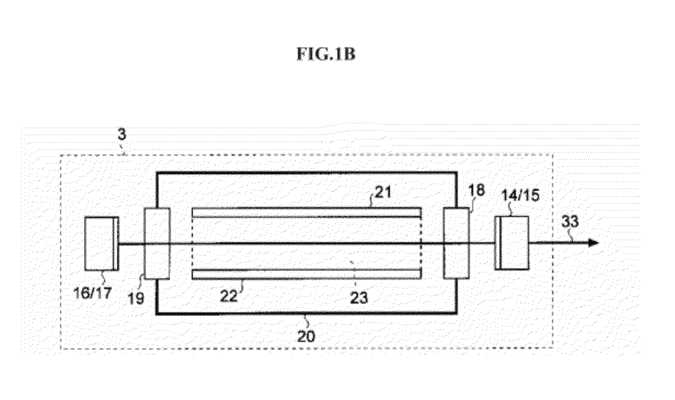

FIG. 1A is a schematic view illustrating an example of a two-stage laser apparatus in a first embodiment of this disclosure. FIG. 1B is a schematic view illustrating an example of an amplifying apparatus in FIG. 1A. FIG. 1B illustrates a section of the amplifying apparatus 3 along a different plane from the section illustrated in FIG. 1A.

As illustrated in FIGS. 1A and 1B, the two-stage laser apparatus (hereinafter referred to as a “laser system”) 1 may include a solid-state laser apparatus 2 and an amplifying apparatus 3. The solid-state laser apparatus 2 may include a wavelength conversion device, for example. The amplifying apparatus 3 may be a discharge-excited ArF excimer amplifier, for example. Between the solid-state laser apparatus 2 and the amplifying apparatus 3, a coherence reduction optical system 4 may be provided. Examples of the coherence reduction optical system 4 may include optical systems such as an optical element array including an optical pulse stretcher or a random phase plate in combination with a collimating optical system.

The solid-state laser apparatus 2 will now be described. The solid-state laser apparatus 2 may include a pumping laser 5, a Ti:sapphire laser 6, an amplifier 7, a beam splitter 81, a high-reflection mirror 82, a wavelength conversion device 9, and a high-reflection mirror 11.

The pumping laser 5 may be a laser configured to generate second harmonic light of a semiconductor laser-excited Nd:YAG laser. The Ti:sapphire laser 6 may include a Ti:sapphire crystal and an optical resonator. The amplifier 7 may include a Ti:sapphire crystal. The wavelength conversion device 9 may include a first wavelength conversion element 91 and a second wavelength conversion element 92. The first wavelength conversion element 91 may include a lithium triborate (LBO) crystal. The second wavelength conversion element 92 may include a KBBF crystal.

The amplifying apparatus 3 will now be described. The amplifying apparatus 3 may include a chamber 20, a pair of discharge electrodes (an anode 21 and a cathode 22), an output coupler 14, and high-reflection mirrors 15, 16, and 17. The chamber 20 may contain laser gas sealed therein. The laser gas may be a mixture of Ar, Ne, F₂, Xe and so forth. The anode 21 and the cathode 22 may be housed in the chamber 20. The anode 21 and the cathode 22 may be arranged in a direction along the plane of FIG. 1B with a space provided therebetween. The anode 21 and the cathode 22 may be arranged with a space provided therebetween in a direction perpendicular to the plane of FIG. 1B. The space between the anode 21 and the cathode 22 may be a discharge space 23. The chamber 20 may be provided with windows 18 and 19 through which pulsed laser light 32 passes. In addition, a high-voltage pulse power supply (not illustrated) may be provided outside the chamber 20.

The output coupler 14 and the high-reflection mirrors 15, 16, and 17 may jointly constitute a ring optical resonator. The output coupler 14 may be an element for allowing part of the light to pass therethrough and reflecting another part of the light.

### 3.2 Operations

The solid-state laser apparatus 2 may output pulsed laser light 31 at a wavelength of about 193 nm. The coherence reduction optical system 4 may reduce the coherence of the pulsed laser light 31. The amplifying apparatus 3 may amplify pulsed laser light 32 whose coherence has been reduced and output the resultant light as pulsed laser light 33. The pulsed laser light 33 may be output to a semiconductor exposure apparatus (not illustrated) and used for exposure.

The pumping laser 5 may output excitation light (also referred to as pumping light) 51 at a wavelength of about 532 nm. Part of the excitation light 51 may pass through the beam splitter 81. The other part of the excitation light 51 may be reflected by the beam splitter 81. Excitation light 51a, which is the part of the excitation light 51 having passed through the beam splitter 81, may excite the Ti:sapphire crystal in the Ti:sapphire laser 6. The Ti:sapphire laser 6 thus excited may output pulsed laser light 31a at a wavelength of about 773.6 nm. The Ti:sapphire laser 6 may include an optical resonator having a wavelength selection element (not illustrated). Accordingly, the Ti:sapphire laser 6 may output pulsed laser light 31a whose spectral linewidth has been narrowed by the wavelength selection element.

Out of the excitation light 51 having been output from the pumping laser 5, excitation light 51b reflected by the beam splitter 81 may be reflected again by the high-reflection mirror 82. The excitation light 51b thus reflected may enter the Ti: sapphire amplifier 7 and excite the Ti: sapphire crystal included in the amplifier 7. With this excitation energy, the amplifier 7 may amplify the pulsed laser light 31a output from the Ti:sapphire laser 6. As a result, the amplifier 7 may output pulsed laser light 31b at a wavelength of about 773.6 nm.

The pulsed laser light 31b output from the Ti:sapphire amplifier 7 may enter the wavelength conversion device 9. The pulsed laser light 31b having entered the wavelength conversion device 9 may enter the first wavelength conversion element 91 first. The pulsed laser light 31b may pass through the LBO crystal serving as a nonlinear optical crystal so as to be converted into pulsed laser light 31b at a wavelength of about 386.8 nm (half the aforementioned wavelength 773.6 nm). The pulsed laser light 31b whose wavelength has been converted may then enter the second wavelength conversion element 92. The pulsed laser light 31b may pass through the KBBF crystal serving as a nonlinear optical crystal so as to be converted into the pulsed laser light 31 at a wavelength of about 193.4 nm (half the aforementioned wavelength 386.8 nm).

The pulsed laser light 31 having passed through the KBBF crystal may be directed by the high-reflection mirror 11 to enter the coherence reduction optical system 4. The coherence of the pulsed laser light 31 may be reduced upon passing through the coherence reduction optical system 4. The pulsed laser light 32 whose coherence has been reduced may enter the amplifying apparatus 3.

A high-voltage pulse power supply (not illustrated) electrically connected to the anode 21 and the cathode 22 in the chamber 20 may apply a high-voltage pulse between the anode 21 and the cathode 22. This may cause a discharge between the anode 21 and the cathode 22. The high-voltage pulse may be applied between the anode 21 and the cathode 22 every time a discharge is allowed to occur in the discharge space 23 with the presence of the pulsed laser light 32 in the discharge space 23.

Part of the pulsed laser light 32 output from the coherence reduction optical system 4 may pass through the output coupler 14 and be reflected by the high-reflection mirror 15. This part of the pulsed laser light 32 may pass through the window 18 and enter the discharge space 23 between the anode 21 and the cathode 22. Control may be made to cause a discharge in the discharge space 23 to occur with the presence of the pulsed laser light 32 in the discharge space 23, whereby the pulsed laser light 32 is amplified. The pulsed laser light 32 thus amplified may be output from the chamber 20 through the window 19. The pulsed laser light 32 thus output may be reflected by the high-reflection mirrors 16 and 17 and may enter the discharge space 23 in the chamber 20 through the window 19 again to be amplified. The pulsed laser light 32 may then be output from the chamber 20 through the window 18. The pulsed laser light 32 thus output may be incident on the output coupler 14. Part of the pulsed laser light 32 may pass through the output coupler 14 and be output from the amplifying apparatus 3 as pulsed laser light 33. The other part of the pulsed laser light 32 may be reflected by the output coupler 14 and returned to the ring optical resonator as feedback light.

While the description above has been made about an example in which the amplifying apparatus 3 includes a ring optical resonator, embodiments are not limited thereto. For example, the amplifying apparatus 3 may include a Fabry-Perot resonator in which an optical resonator is provided in an amplifier.

The first embodiment illustrates the wavelength conversion device 9 in the solid-state laser and the laser system 1 including the solid-state laser. The coherence reduction optical system 4 and the amplifying apparatus 3, for example, illustrated in FIG. 1A are not indispensable components to put this disclosure into practice. In addition, the pulsed laser light 31b, before its wavelength is converted by the wavelength conversion device 9, is not necessarily output from a laser apparatus including the Ti:sapphire laser 6.

### 4. WAVELENGTH CONVERSION DEVICE INCLUDING TWO PRISMS BROUGHT INTO OPTICAL CONTACT WITH NONLINEAR OPTICAL CRYSTAL

### Second Embodiment

A second embodiment of this disclosure will now be described. In the second embodiment, the second wavelength conversion element 92 in the first embodiment is embodied by a wavelength conversion element 101A.

An issue associated with a KBBF crystal will now be discussed. The KBBF crystal is hard to grow in directions other than the direction of its optical axis (Z axis) at present. In addition, the KBBF crystal is hard to grow to be thicker than about 2.5 mm in the direction of its optical axis at present. These make it difficult to cut the KBBF crystal along its plane perpendicular to the phase matching direction with a sufficient thickness. Furthermore, the KBBF crystal has strong cleavage. This makes it difficult to precisely cut the KBBF crystal along its plane perpendicular to the phase matching direction and to optically polish this plane at present. For these reasons, the plane of the KBBF crystal perpendicular to its optical axis is used as a surface on which light is incident or as a surface from which light is output in some cases.

The KBBF crystal has a large refractive index. With such KBBF crystal placed in the atmosphere, the second harmonic light (193.4 nm) generated in the KBBF crystal may be substantially totally reflected by the boundary between the atmosphere and a light output surface under some conditions. Thus, the second harmonic light may not be extracted in the KBBF crystal in some cases.

To overcome this issue, film coating may be applied to a surface on which the light is incident and a surface from which the light is output of the KBBF crystal. The film-coated KBBF crystal may be sandwiched by two prisms, one on the surface on which the light is incident and the other surface from which the light is output. The coating films are preferably thick enough to achieve sufficient surface roughness for optical contact on the surfaces. With the coating films formed, even when surface on which the light is incident and the surface from which the light is output of the KBBF crystal have certain levels of surface roughness, the surface roughness is planarized to be the surface roughness of the films. Accordingly, optical contact is made between these planarizing films and prisms. This configuration may prevent total reflection of the second harmonic light at the boundary.

### 4.1 Configuration

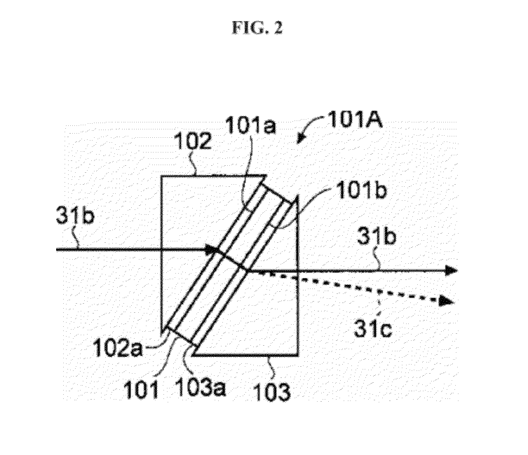

FIG. 2 is a schematic view illustrating the wavelength conversion element 101A in a wavelength conversion device in the second embodiment. A KBBF crystal 101 is used as a nonlinear optical crystal in this embodiment.

As illustrated in FIG. 2, the wavelength conversion element 101A may include the KBBF crystal 101, a coating film (third film) 102a formed on one main surface of the KBBF crystal 101, and another coating film (first film) 103a formed on the other main surface of the KBBF crystal 101. In the following description, one main surface is referred to as an incident surface 101a and the other main surface is referred to as an output surface 101b. The coating films 102a and 103a may be thick enough to provide sufficient surface roughness for optical contact on the surfaces.

The wavelength conversion element 101A may also include a prism (second prism) 102 and another prism (first prism) 103. The prism 102 may be provided to the incident surface 101a of the KBBF crystal 101 with the coating film 102a interposed therebetween. The prism 102 may be joined to the coating film 102a through optical contact.

The prism 103 may be provided to the output surface 101b of the KBBF crystal 101 with the coating film 103a interposed therebetween. The prism 103 may be joined to the coating film 103a through optical contact.

### 4.2 Operations

For example, the pulsed laser light 31b (386.8 nm) having passed through the first wavelength conversion element 91 may enter the prism 102. The pulsed laser light 31b may pass through the optical-contact surface between the prism 102 and the coating film 102a. The pulsed laser light 31b may then pass through the coating film 102a and enter the KBBF crystal 101. In the KBBF crystal 101, second harmonic light 31c (193.4 nm) whose fundamental wave light is the pulsed laser light 31b (386.8 nm) may be generated. The pulsed laser light 31b and the second harmonic light 31c may pass through the coating film 103a and the optical-contact surface between the coating film 103a and the prism 103. The pulsed laser light 31b and the second harmonic light 31c may then pass through the prism 103 to be output therefrom. The pulsed laser light 31b and the second harmonic light 31c have different refractive angles and can be output from the prism 103 in a split manner. The second harmonic light 31c may be output from the wavelength conversion device 9 as the pulsed laser light 31. The pulsed laser light 31 may be amplified by the amplifying apparatus 3 such as an ArF excimer amplifier.

### 4.3 Effect(s)

In the wavelength conversion element 101A, total reflection of the pulsed laser light 31b or the second harmonic light 31c can be prevented at respective boundaries between the prism 102, the coating film 102a, the KBBF crystal 101, the coating film 103a, and the prism 103. If a prism is directly brought into optical contact with the KBBF crystal 101, the boundary between the KBBF crystal 101 and the prism may be damaged due to pulsed laser light, which can shorten the lifetime of the KBBF crystal 101. In the second embodiment, film coating is applied to the surface of the KBBF crystal 101, and a prism may be brought into contact with this film. Accordingly, potential damage due to pulsed laser light can be reduced, which can extend the lifetime of the wavelength conversion element 101A.

While the coating films 102a and 103a are provided to the incident surface 101a and the output surface 101b, respectively, of the KBBF crystal 101 and these coating films 102a and 103a are joined to the prisms 102 and 103, respectively, through optical contact in the second embodiment, embodiments are not limited thereto. For example, the wavelength conversion element 101A may include either one of the coating films 102a and 103a. In this case, film coating may be applied to one boundary on the KBBF crystal 101 that is affected to a greater extent by the pulsed laser light 31b or the second harmonic light 31c. On the surface without film coating, the prism may be directly brought into optical contact with the KBBF crystal 101.

### 5. WAVELENGTH CONVERSION DEVICE INCLUDING OXIDE FILM COATED PRISM BROUGHT INTO OPTICAL CONTACT WITH NONLINEAR OPTICAL CRYSTAL

### Third Embodiment

A more specific configuration of the wavelength conversion element 101A in the second embodiment will now be described as a third embodiment of this disclosure. The KBBF crystal 101 is used as a nonlinear optical crystal in this embodiment.

### 5.1 Configuration

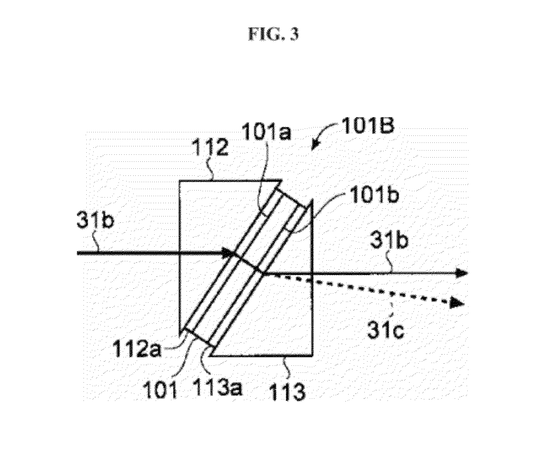

FIG. 3 is a schematic view illustrating a wavelength conversion element 101B in a wavelength conversion device in the third embodiment. As illustrated in FIG. 3, the wavelength conversion element 101B may include the KBBF crystal 101, a coating film (third film) 112a, another coating film (first film) 113a, a prism (second prism) 112, and another prism (first prism) 113.

The coating film 112a may be provided on the incident surface 101a of the KBBF crystal 101. The coating film 113a may be provided on the output surface 101b of the KBBF crystal 101. The coating films 112a and 113a may be thick enough to provide sufficient surface roughness for optical contact on the surfaces.

The prism 112 may be joined to the coating film 112a provided on the incident surface 101a of the KBBF crystal 101 through optical contact. The prism 113 may be joined to the coating film 113a provided on the output surface 101b of the KBBF crystal 101 through optical contact. The prism 112, the coating film 112a, the coating film 113a, and the prism 113 may be made of material having such a refractive index that total reflection of laser light at their boundaries can be prevented.

The coating film 112a may be a film containing at least one of oxide and fluoride. Alternatively, the coating film 112a may be a multilayered film including a layer (second layer) containing at least one of oxide and fluoride on the surface in contact with the prism 112. In a similar manner, the coating film 113a may be a film containing at least one of oxide and fluoride. Alternatively, the coating film 113a may be a multilayered film including a layer (first layer) containing at least one of oxide and fluoride on the surface in contact with the prism 113.

A material for making the coating film 112a or the layer (second layer) in the coating film 112a in contact with the prism 112 may contain at least one of SiO₂, MgF₂, LaF₃, and GdF₃. In a similar manner, a material for making the coating film 113a or the layer (first layer) in the coating film 113a in contact with the prism 113 may contain at least one of SiO₂, MgF₂, LaF₃, and GdF₃.

A material for making the prism 112 may contain at least one of SiO₂ crystal, CaF₂ crystal, and MgF₂ crystal. In a similar manner, a material for making the prism 113 may contain at least one of SiO₂ crystal, CaF₂ crystal, and MgF₂ crystal.

Using a material having the same molecular composition for making the coating film 112a and the prism 112 can enhance joining strength of the coating film 112a to the prism 112 and facilitate refraction index matching between them. In a similar manner, using a material having the same molecular composition for making the coating film 113a and the prism 113 can enhance joining strength of the coating film 113a to the prism 113 and facilitate refraction index matching between them.

Synthetic silica or quartz, for example, may be used for making the prisms 112 and 113.

An electron beam method or a sputtering method, for example, may be employed for making the coating films 112a and 113a. Deposition methods are not limited to these, and various types of film deposition methods can be employed. The coating films 112a and 113a thus provided can reduce the surface roughness on the incident surface 101a and the output surface 101b, respectively, of the KBBF crystal 101.

### 5.2 Effect(s)

In the third embodiment, the prisms may be brought into optical contact with the respective films made of a material having the same molecular composition. This configuration can reduce potential damage on the boundaries due to pulsed laser light and extend the lifetime of the wavelength conversion element 101B.

The prism 112 or 113, when made of quartz, is preferably so processed that the optical axis of the quartz coincides with the polarizing direction of the pulsed laser light 31b. Each of the coating films 112a and 113a is preferably made of a SiO₂ film by sputtering. Accordingly, compaction of the SiO₂ film due to the second harmonic light 31c can be prevented. The use of quartz is considered to make compaction due to laser light at a wavelength of 193.4 nm less likely than with the use of synthetic silica. Quartz is therefore preferably used for making the first prism, in particular.

### 6. WAVELENGTH CONVERSION DEVICE INCLUDING PRISM BROUGHT INTO OPTICAL CONTACT WITH OXIDE OR FLUORIDE FILM COATED NONLINEAR OPTICAL CRYSTAL

### Fourth Embodiment

Another specific configuration of the wavelength conversion element 101A in the second embodiment will now be described as a fourth embodiment of this disclosure. The KBBF crystal 101 is used as a nonlinear optical crystal in this embodiment.

### 6.1 Configuration

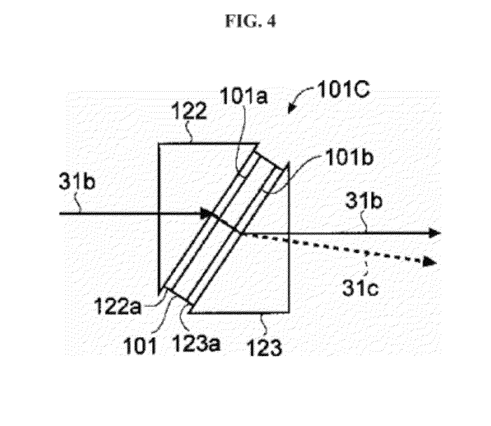

FIG. 4 is a schematic view illustrating a wavelength conversion element 101C in a wavelength conversion device in the fourth embodiment. As illustrated in FIG. 4, the wavelength conversion element 101C may include the KBBF crystal 101, a coating film (third film) 122a, another coating film (first film) 123a, a prism (second prism) 122, and another prism (first prism) 123.

The coating film 122a may be provided on the incident surface 101a of the KBBF crystal 101. The coating film 123a may be provided on the output surface 101b of the KBBF crystal 101. The coating films 122a and 123a may be thick enough to provide sufficient surface roughness for optical contact on the surfaces.

The prism 122 may be joined to the coating film 122a provided on the incident surface 101a of the KBBF crystal 101 through optical contact. The prism 123 may be joined to the coating film 123a provided on the output surface 101b of the KBBF crystal 101 through optical contact. The prism 122, the coating film 122a, the coating film 123a, and the prism 123 may be made of a material having such a refractive index that total reflection of laser light at their boundaries can be prevented.

Oxides, for example, may be used for making the coating film 122a and the prism 122 on the incident side of the pulsed laser light 31b. The coating film 122a may be a multilayered film including a layer (second layer) containing an oxide on the surface in contact with the prism 122. Using oxides for making both contact surfaces of the coating film 122a and the prism 122 can improve joinability of the two surfaces and facilitate refraction index matching between them. Examples of the oxides for making the coating film 122a and the prism 122 may include SiO₂. Alternatively, fluorides may be used for making the coating film 122a and the prism 122.

Fluorides, for example, may be used for making the coating film 123a and the prism 123 on the output side of the pulsed laser light 31b and the second harmonic light 31c. Fluoride material has smaller absorptivity of laser light at a wavelength of 193.4 nm than oxide material does. The use of the fluoride material, therefore, is considered to make compaction due to the second harmonic light 31c less likely than with the use of the oxide material. The coating film 123a may be a multilayered film including a layer (first layer) containing a fluoride on the surface in contact with the prism 123. Using fluorides for making both contact surfaces of the coating film 123a and the prism 123 can improve joinability of the two surfaces and facilitate refraction index matching between them. Examples of fluorides for making the coating film 123a may include MgF₂, LaF₃, and GdF₃. Examples of fluorides for making the prism 123 may include CaF₂ and MgF₂.

An electron beam method or a sputtering method, for example, may be employed for making the coating films 122a and 123a. Deposition methods are not limited to these, and various types of film deposition methods can be employed. The coating films 122a and 123a thus provided can reduce the surface roughness on the incident surface 101a and the output surface 101b, respectively, of the KBBF crystal 101.

### 6.2 Effect(s)

In the fourth embodiment, the prisms may be brought into optical contact with the respective films made of a material having the same or similar compositions on both the incident surface 101a and the output surface 101b of the KBBF crystal 101. This configuration can reduce potential damage on the boundaries due to pulsed laser light and extend the lifetime of the wavelength conversion element 101C.

The prism 123, when made of MgF₂, is preferably so processed that the optical axis of the prism 123 coincides with the polarizing direction of the pulsed laser light 31b.

### 7. WAVELENGTH CONVERSION DEVICE INCLUDING PRISM FILM BROUGHT INTO OPTICAL CONTACT WITH NONLINEAR OPTICAL CRYSTAL FILM

### Fifth Embodiment

Yet another specific configuration of the wavelength conversion element 101A in the second embodiment will now be described as a fifth embodiment of this disclosure. The KBBF crystal 101 is used as a nonlinear optical crystal in this embodiment.

### 7.1 Configuration

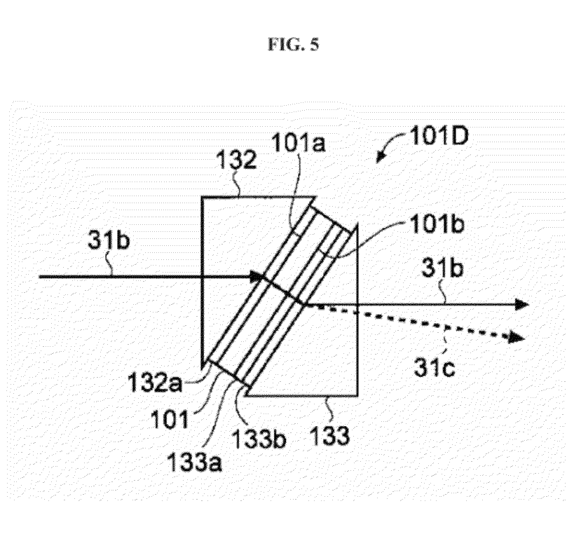

FIG. 5 is a schematic view illustrating a wavelength conversion element 101D in a wavelength conversion device in the fifth embodiment. As illustrated in FIG. 5, the wavelength conversion element 101D may include the KBBF crystal 101, a coating film (third film) 132a, another coating film (first film) 133a, a prism (second prism) 132, and another prism (first prism) 133. The prism (first prism) 133 may include a coating film (second film) 133b on the surface in contact with the coating film (first film) 133a.

The coating film 132a may be provided on the incident surface 101a of the KBBF crystal 101. The coating film 133a may be provided on the output surface 101b of the KBBF crystal 101. The coating film 133b may be provided on one surface of the prism 133 closer to the KBBF crystal 101. The coating films 132a and 133a may be thick enough to provide sufficient surface roughness for optical contact on the surfaces. In a similar manner, the coating film 133b may be thick enough to provide sufficient surface roughness for optical contact on the surfaces.

The prism 132 may be joined to the coating film 132a provided on the incident surface 101a of the KBBF crystal 101 through optical contact. The coating film 133b for the prism 133 may be joined to the coating film 133a provided on the output surface 101b of the KBBF crystal 101 through optical contact. In this case, the coating films are joined through optical contact, whereby they can be favorably joined. Another coating film may be applied to the prism 132 on the incident surface 101a side of the KBBF crystal 101 in a manner similar to that on the output surface 101b side, and this coating film may be joined to the coating film 132a for the KBBF crystal 101 through optical contact. The prism 132 and the coating film 132a, the coating film 132a and the KBBF crystal 101, the KBBF crystal 101 and the coating film 133a, the coating film 133a and the coating film 133b, and the coating film 133b and the prism 133 may respectively be made of a material having such a refractive index that total reflection of laser light at their respective boundaries can be prevented.

Oxides, for example, may be used for making the coating film 132a and the prism 132 on the incident side of the pulsed laser light 31b. The coating film 132a may be a multilayered film including a layer (second layer) containing an oxide on the surface in contact with the prism 132. Using oxides for making both contact surfaces of the coating film 132a and the prism 132 can improve joinability of the two surfaces and facilitate refraction index matching between them. Examples of the oxides for making the coating film 132a and the prism 132 may include SiO₂. Alternatively, a fluoride may be used for making the coating film 132a. The fluoride may contain at least one of MgF₂, LaF₃, and GdF₃. The material of the prism 132 is not limited to SiO₂ crystal but may contain at least one of CaF₂ crystal and MgF₂ crystal. For applying a coating film to the prism 132, a material containing at least one of MgF₂, LaF₃, GdF₃, and SiO₂ may be used.

Fluorides or oxides, for example, may be used for making the coating film 133a, the coating film 133b, and the prism 133 on the output side of the pulsed laser light 31b and the second harmonic light 31c. Fluoride material has smaller absorptivity of laser light at a wavelength of 193.4 nm than oxide material does. The use of the fluoride material, therefore, is considered to make compaction due to the second harmonic light 31c less likely than with the use of oxide material. The coating film 133a may be a multilayered film including a layer (first layer) containing an oxide or a fluoride on the surface in contact with the coating film 133b. The coating film 133b may be a multilayered film including a layer containing an oxide or a fluoride on the surface in contact with the coating film 133a. The facing surfaces of the coating film 133a and the coating film 133b are preferably made of a material having the same or similar composition. Using a material having the same or similar composition for making the facing surfaces of the coating film 133a and the coating film 133b can improve joinability of the two surfaces and facilitate refraction index matching between them. Examples of the material for making the coating films 133a and 133b may include MgF₂, LaF₃, GdF₃, and SiO₂. A material for making the prism 133 may contain at least one of CaF₂ crystal and MgF₂ crystal. It is particularly preferable that SiO₂ be used for making the coating films 133a and 133b and CaF₂ crystal for making the prism 133. Alternatively, SiO₂ crystal may be used for making the prism 133.

The coating films 132a and 133a may be deposited on the incident surface 101a and the output surface 101b, respectively, of the KBBF crystal 101 by an electron beam deposition or sputtering, for example. The coating film 133b may be deposited on the surface of the prism 133 closer to the KBBF crystal 101 by an electron beam deposition or sputtering, for example. Deposition methods are not limited to these, and various types of film deposition methods can be employed. The coating films 132a and 133a thus provided can reduce the surface roughness on the incident surface 101a and the output surface 101b, respectively, of the KBBF crystal 101. The coating film 133b can reduce the surface roughness on the surface of the prism 133 closer to the KBBF crystal 101.

### 7.2 Effect(s)

In the fifth embodiment, the prism may be brought into optical contact with the film made of a material having the same or similar compositions on the incident surface 101a of the KBBF crystal 101. In addition, the films made of a material having the same or similar compositions may be brought into optical contact with each other on the output surface 101b of the KBBF crystal 101. This configuration can reduce potential damage on the boundaries due to pulsed laser light 31b and extend the lifetime of the wavelength conversion element 101D.

Using CaF₂ or other fluoride crystal materials for making the prism 133 can improve durability of the wavelength conversion element 101D compared with the use of an oxide material.

### 8. WAVELENGTH CONVERSION DEVICE INCLUDING PRISM BROUGHT INTO OPTICAL CONTACT WITH NONLINEAR OPTICAL CRYSTAL HAVING BUFFER LAYERS AND FILMS THEREON

### Sixth Embodiment

Yet another specific configuration of the wavelength conversion element 101A in the second embodiment will now be described as a sixth embodiment of this disclosure. The KBBF crystal 101 is used as a nonlinear optical crystal in this embodiment.

### 8.1 Configuration

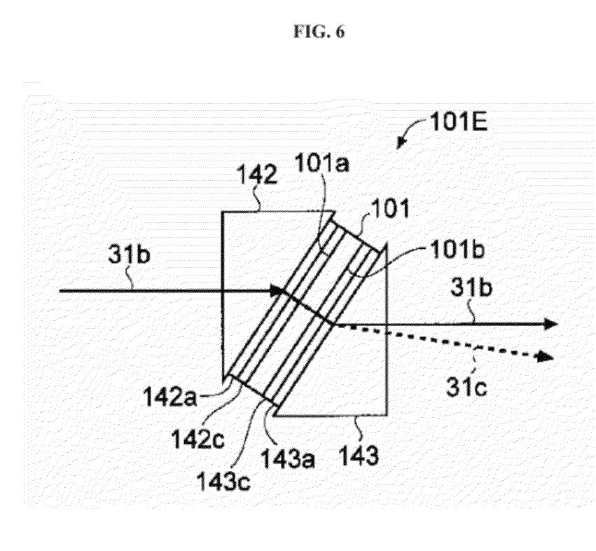

FIG. 6 is a schematic view illustrating a wavelength conversion element 101E in a wavelength conversion device in the sixth embodiment. As illustrated in FIG. 6, the wavelength conversion element 101E may include the KBBF crystal 101, a coating film (third film) 142a, another coating film (first film) 143a, a buffer layer (second buffer layer) 142c, another buffer layer (first buffer layer) 143c, a prism (second prism) 142, and another prism (first prism) 143.

The buffer layer 142c may be provided on the incident surface 101a of the KBBF crystal 101. The coating film 142a may be provided on the buffer layer 142c. The buffer layer 143c may be provided on the output surface 101b of the KBBF crystal 101. The coating film 143a may be provided on the buffer layer 143c. The buffer layer 142c and the coating film 142a may together be thick enough to provide sufficient surface roughness for optical contact on the surfaces. In a similar manner, the buffer layer 143c and the coating film 143a may together be thick enough to provide sufficient surface roughness for optical contact on the surfaces.

The prism 142 may be joined to the coating film 142a provided on the incident surface 101a side of the KBBF crystal 101 through optical contact. The prism 143 may be joined to the coating film 143a provided on the output surface 101b side of the KBBF crystal 101 through optical contact. The prism 142 and the coating film 142a, the coating film 142a and the buffer layer 142c, the buffer layer 142c and the KBBF crystal 101, the KBBF crystal 101 and the buffer layer 143c, the buffer layer 143c and the coating film 143a, and the coating film 143a and the prism 143 may each be made of a material having such a refractive index that total reflection of laser light at their respective boundaries can be prevented.

A material containing at least one of fluorides and oxides, for example, may be used for making the coating films 142a and 143a and the prisms 142 and 143. The coating film 142a may be a multilayered film including a layer (second layer) containing an oxide or a fluoride on the surface in contact with the prism 142. The coating film 143a may be a multilayered film including a layer (first layer) containing an oxide or a fluoride on the surface in contact with the prism 143. On the incident surface 101a side of the KBBF crystal 101, a material having the same or similar composition may be used for making the prism 142 and the coating film 142a. On the output surface 101b side of the KBBF crystal 101, a material having the same or similar composition may be used for making the prism 143 and the coating film 143a. Using a material having the same or similar composition can make joining of the two surfaces easy. Furthermore, using fluorides for making the coating films 142a and 142b and prisms 142 and 143 can facilitate refractive index matching between them. Examples of the material for making the coating films 142a and 143a may contain at least one of MgF₂, LaF₃, GdF₃, and SiO₂. A material for making the prisms 142 and 143 may contain at least one of CaF₂ crystal, MgF₂ crystal, and SiO₂ crystal. It is particularly preferable that SiO₂ be used for making the coating films 142a and 143a and synthetic silica (SiO₂) for making the prisms 142 and 143.

A material containing at least one of Al₂O₃, HfO₂, ZrO₂, and ScO₂, for example, may be used for making the buffer layers 142c and 143c. The multilayered film composed of the coating film 142a and the buffer layer 142c can reduce the surface roughness on the incident surface 101a of the KBBF crystal 101. The multilayered film composed of the coating film 143a and the buffer layer 143c can reduce the surface roughness on the output surface 101b of the KBBF crystal 101.

Sputtering, chemical vapor deposition (CVD), and atomic layer deposition (ALD), for example, may be employed for depositing the buffer layers 142c and 143c. The coating films 142a and 143a may be deposited, for example, by electron beam deposition or sputtering on the buffer layers 142c and 143c, respectively, provided on the KBBF crystal 101. Deposition methods are not limited to these, and various types of film deposition methods can be employed.

### 8.2 Effect(s)

In the sixth embodiment, the prisms may be brought into optical contact with the respective films made of a material having the same or similar compositions on the incident surface 101a and the output surface 101b of the KBBF crystal 101. This configuration can reduce potential damage on the boundaries due to the pulsed laser light 31b and extend the lifetime of the wavelength conversion element 101E.

The KBBF crystal 101 is a fluoride crystal. When SiO₂ is used for making the coating films 142a and 143a, SiF₄ or the like may be produced as a result of contact between the KBBF crystal 101 and the SiO₂ coating films. SiF₄ absorbs ultraviolet rays, and thus may reduce the conversion efficiency of the wavelength conversion device. In the sixth embodiment, the buffer layers 142c and 143c are provided on the incident surface 101a and the output surface 101b, respectively, of the KBBF crystal 101, which makes production of SiF₄ or the like less likely. As a result, ultraviolet absorption by SiF₄ can be reduced, and reduction in the conversion efficiency of the wavelength conversion device can be suppressed.

Providing the buffer layer 142c between the KBBF crystal 101 and the coating film 142a can reduce internal stress due to the difference in the coefficients of thermal expansion between the KBBF crystal 101 and the coating film 142a. In a similar manner, providing the buffer layer 143c between the KBBF crystal 101 and the coating film 143a can reduce internal stress due to the difference in the coefficients of thermal expansion between the KBBF crystal 101 and the coating film 143a. As a result, the risk of mechanical fracture of the wavelength conversion device due to internal stress resulting from temperature changes can be suppressed.

### 9. WAVELENGTH CONVERSION DEVICE INCLUDING ONE PRISM BROUGHT INTO OPTICAL CONTACT WITH FILM COATED NONLINEAR OPTICAL CRYSTAL

### Seventh Embodiment

A seventh embodiment of this disclosure will now be described. In the seventh embodiment, the second wavelength conversion element 92 in the first embodiment may be embodied with a wavelength conversion element 101F.

### 9.1 Configuration

While the two opposite surfaces of the KBBF crystal 101, which is a nonlinear optical crystal, serve as the incident surface 101a on which laser light is incident and the output surface 101b from which laser light is outputted and both surfaces are provided with prisms with a coating film interposed therebetween in the second and third embodiments, embodiments are not limited thereto. One surface of the KBBF crystal 101 may serve as an incident and output surface on which laser light is incident and from which laser light is outputted, and this surface may be provided with a prism with a coating film interposed therebetween.

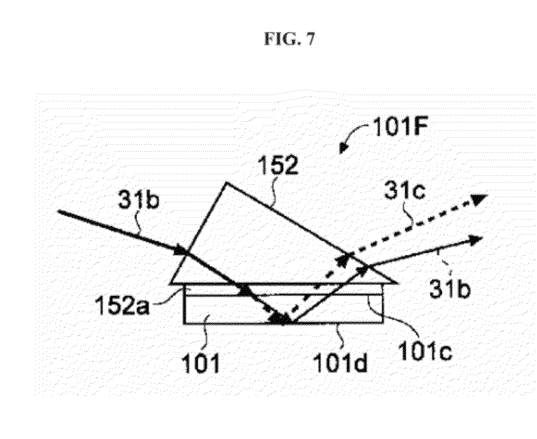

FIG. 7 is a schematic view illustrating the wavelength conversion element 101F in a wavelength conversion device in the seventh embodiment. As illustrated in FIG. 7, the wavelength conversion element 101F may include the KBBF crystal 101, a coating film (first film) 152a, and a prism (first prism) 152.

The coating film 152a may be provided on an incident-output surface 101c of the KBBF crystal 101. The prism 152 may be joined to the coating film 152a provided on the incident-output surface 101c of the KBBF crystal 101 through optical contact. The prism 152 and the coating film 152a may be made of a material having such a refractive index that total reflection of laser light at their boundary can be prevented.

A material for making the prism 152 and the coating film 152a may be selected from the materials for making the prisms and the coating films in the third through sixth embodiments. A material for making the prism 152 and the coating film 152a are preferably a fluoride material having small absorptivity of laser light at a wavelength of 193.4 nm. The coating film 152a may be the multilayered film described above.

The prism 152 may include a coating film (second film) similar to that in the fifth embodiment on the surface in contact with the coating film 152a. Furthermore, a buffer layer (first buffer layer) similar to that in the sixth embodiment may be provided on the KBBF crystal 101, and the coating film 152a may be provided on the buffer layer.

### 9.2 Operations

For example, the pulsed laser light 31b (wavelength of 386.8 nm) having passed through the first wavelength conversion element 91 may enter the prism 152. The pulsed laser light 31b may then pass through the prism 152, and enter the KBBF crystal 101 through the coating film 152a.

At least part of the pulsed laser light 31b at a wavelength of 386.8 nm may be wavelength-converted upon passing through the KBBF crystal 101 to be the second harmonic light 31c at a wavelength of 193.4 nm. The pulsed laser light 31b and the second harmonic light 31c with its wavelength converted may be highly reflected at an opposite surface 101d of the incident-output surface 101c of the KBBF crystal 101. The pulsed laser light 31b and the second harmonic light 31c can be highly reflected upon being incident on the surface 101d at an angle of total reflection determined based on the refractive index of the KBBF crystal 101 and the refractive index of the air.

The pulsed laser light 31b and the second harmonic light 31c highly reflected at the surface 101d may pass through the KBBF crystal 101 again. Here, the pulsed laser light 31b and the second harmonic light 31c may travel along different optical paths because of the difference in their refractive indexes depending on their wavelengths.

The pulsed laser light 31b and the second harmonic light 31c propagating along different optical paths may, through the coating film 152a, enter the prism 152 again and then be output with their optical paths refracted by the prism 152, respectively. The pulsed laser light 31b and the second harmonic light 31c may be thus output from the wavelength conversion element 101F along different optical paths.

### 9.3 Effect(s)

The seventh embodiment requires only one prism, thereby simplifying the configuration of the wavelength conversion element 101F. In addition, since the reflected pulsed laser light 31b travels through the KBBF crystal 101, the optical path of the pulsed laser light 31b inside the KBBF crystal 101 can be extended. This can improve conversion efficiency from the pulsed laser light 31b into the second harmonic light 31c.

The above-described embodiments and the variations thereof are merely examples for implementing this disclosure, and this disclosure is not limited thereto. Making various variations according to the specifications or the like is within the scope of this disclosure, and other various embodiments are possible within the scope of this disclosure. For example, the variations illustrated for particular ones of the embodiments can be applied to other embodiments as well (including the other embodiments described herein).

The terms used in this specification and the appended claims should be interpreted as “non-limiting.” For example, the terms “include” and “be included” should be interpreted as “including the stated elements but not limited to the stated elements.” The term “have” should be interpreted as “having the stated elements but not limited to the stated elements.” Further, the modifier “one (a/an)” should be interpreted as “at least one” or “one or more.”

While a single amplifier 7 is provided in the embodiments described above, a plurality of amplifiers 7 may be used instead. While the Ti:sapphire laser 6 and the amplifier 7 are pumped by the common pumping laser 5, separate pumping lasers may be used instead. As the pumping laser 5, a laser that generates second harmonic light of a Nd:YLF laser or a Nd:YVO₄ laser may be used. Instead of the Ti:sapphire laser 6, a laser that generates second harmonic light of an erbium-doped optical fiber laser may be used. This laser may be pumped by a semiconductor laser. The wavelength conversion device 9 is not limited to the configurations described in this disclosure, and may take any form as long as it converts incident light into light whose wavelength is in the band of amplification wavelength of the amplifying apparatus 3, e.g., about 193.4 nm. Examples of a nonlinear optical crystal included in the wavelength conversion device 9 may include a cesium lithium triborate (CLBO) crystal, instead of the LBO crystal.

What is claimed is:

1. A wavelength conversion device, comprising:
a nonlinear crystal including a first surface;
a first film to be joined to the first surface and including at least one layer; and
a first prism to be joined to the first film.

2. The wavelength conversion device according to claim 1, wherein the first film and the first prism are joined through an optical contact.

3. The wavelength conversion device according to claim 1, wherein the nonlinear crystal is a KBBF crystal.

4. The wavelength conversion device according to claim 1, wherein the first film includes a first layer containing at least one of an oxide and a fluoride on a surface to be joined to the first prism.

5. The wavelength conversion device according to claim 1, wherein the first film includes a first layer containing at least one of SiO₂, MgF₂, LaF₃, and GdF₃ on a surface to be joined to the first prism.

6. The wavelength conversion device according to claim 1, wherein a material for the first prism includes at least one of a SiO₂ crystal, a CaF₂ crystal, and a MgF₂ crystal.

7. The wavelength conversion device according to claim 1, wherein the first prism includes a second film including at least one layer on a surface to be joined to the first film.

8. The wavelength conversion device according to claim 7, wherein the second film includes a film containing at least one of SiO₂, MgF₂, LaF₃, and GdF₃ on the surface to be joined to the first film.

9. The wavelength conversion device according to claim 1, wherein the first film includes a first buffer layer on a surface to be joined to the first prism.

10. The wavelength conversion device according to claim 9, wherein a material for the first buffer layer includes at least one of Al₂O₃, HfO₂, ZrO₂, and ScO₂.

11. The wavelength conversion device according to claim 10, wherein a material for the first prism includes at least one of a SiO₂ crystal, a CaF₂ crystal, and a MgF₂ crystal.

12. The wavelength conversion device according to claim 1, further comprising:
a third film to be joined to a second surface of the nonlinear crystal, the second surface lying opposite to the first surface; and
a second prism to be joined to the third film.

13. The wavelength conversion device according to claim 12, wherein the third film and the second prism are joined through an optical contact.

14. The wavelength conversion device according to claim 12, wherein the third film includes a second layer containing at least one of an oxide and a fluoride on a surface to be joined to the second prism.

15. The wavelength conversion device according to claim 12, wherein the third film includes a second layer containing at least one of SiO₂, MgF₂, LaF₃, and GdF₃ on a surface to be joined to the second prism.

16. The wavelength conversion device according to claim 12, wherein a material for the second prism includes at least one of a SiO₂ crystal, synthetic silica, a CaF₂ crystal, and a MgF₂ crystal.

17. The wavelength conversion device according to claim 12, wherein the third film includes a second buffer layer on a surface to be joined to the first prism.

18. The wavelength conversion device according to claim 17, wherein a material for the second buffer layer includes at least one of Al₂O₃, HfO₂, ZrO₂, and ScO₂.

19. The wavelength conversion device according to claim 18, wherein a material for the second prism includes at least one of a SiO₂ crystal, synthetic silica, a CaF₂ crystal, and a MgF₂ crystal.

20. A solid-state laser apparatus comprising:
a laser configured to output laser light;
an amplifier configured to amplify the laser light; and
the wavelength conversion device as claimed in claim 1 configured to convert a wavelength of the laser light after being amplified.

21. A solid-state laser apparatus comprising:
a laser configured to output laser light;
an amplifier configured to amplify the laser light; and
the wavelength conversion device as claimed in claim 12 configured to convert a wavelength of the laser light after being amplified.

22. A laser system comprising:
the solid-state laser apparatus as claimed in claim 20; and
an amplifying apparatus configured to amplify the laser light from the solid-state laser apparatus.

23. A laser system comprising:
the solid-state laser apparatus as claimed in claim 21; and
an amplifying apparatus configured to amplify the laser light from the solid-state laser apparatus.
